(19) United States
(12) Patent Application Publication
(10) Pub. No.: US 2015/0188019 A1
(43) Pub. Date: Jul. 2, 2015

(54) Device, System and Method For Converting Solar Thermal Energy To Electricity By Thermoelectric Means

(71) Applicant: Anthony Paul Corrado, Elbert, CO (US)

(72) Inventor: Anthony Paul Corrado, Elbert, CO (US)

(21) Appl. No.: 14/141,958

(22) Filed: Dec. 27, 2013

(51) Int. Cl. H01L 35/32; H01L 35/34

(52) U.S. Cl. CPC H01L 35/32; H01L 35/34

(57) ABSTRACT

This utility patent invention submission is for a thermoelectric solar energy conversion system. The patent is for the design, method and processes associated with manufacturing panels containing the thermoelectric elements, associated layers and thermal heat transfer methodologies. The exemplary embodiment utilizes 2D or 3D metal printing techniques. The invention produces both electrical power from the thermoelectric elements as well as heat from the cooling of these thermoelectric elements which can be used as a source of hot water.

### FIELD OF THE INVENTION

The invention relates generally to the field of solar energy conversion. More specifically, the invention relates to a device, system and method for collecting and converting incident solar thermal energy into electricity via an array of thermoelectric effect devices. Thermoelectric effect devices are also commonly known as thermocouples and these terms are used interchangeably in this document. This invention also utilizes the heat removed (array cooling energy) from the thermo electric device array as a secondary heat source.

### BACKGROUND

Conventional solar energy conversion devices depend on a silicon substrate doped with various materials to produce free electron flow as a result of solar energy being absorbed. The energy transferred from the photons causes electrons to be knocked loose from their atoms, allowing them to flow from the material to produce electricity. Due to the special composition of solar cells, the electrons generally only move in a single direction. An array of solar cells can be sequentially assembled into solar panels and multiple panels are subsequently assembled into solar panel arrays. These assemblies convert solar energy into a usable amount of direct current (DC) electricity which can be converted into alternating current (AC) by an inverter. This energy can be fed into an electrical energy supply grid or can be stored in batteries for subsequent use.

Alternative methods of solar energy conversion that do not use photovoltaic operations instead convert the thermal energy portion of the incident radiation into heat. Typically, these types of systems collect the solar thermal energy and focus it onto a collector through which a fluid is flowing. The collector heats the fluid and generally converts the fluid to a vapor state. This fluid flows through a turbine to drive a conventional electrical generator thereby producing electrical energy as an output. The vapor is cooled during this process by expansion in the turbine and re-condenses into a fluid for a continuous flow operation.

This invention generates both useful electricity as well as providing a source of thermal energy for secondary recovery such as providing hot water for heating.

### BRIEF DESCRIPTION OF THE DRAWINGS

The present invention will be more closely understood hereinafter by reference to the drawings of which:

FIG. 1 is a top view of a thermoelectric effect device junction array sub-system with each of the junctions serially coupled in accordance with an exemplary embodiment;

FIG. 2 is a schematic view of a thermoelectric effect device junction array subsystem coupled to a power bus through a diode in accordance with an exemplary embodiment;

FIG. 3 is a top view of a plurality of individual thermoelectric effect device array subassemblies coupled to a power bus in accordance with an exemplary embodiment;

FIG. 4a is a cross-sectional view of a thermoelectric effect device junction array subsystem with temporary filler material in substrate holes in accordance with an exemplary embodiment;

FIG. 4b is a cross-sectional view of a thermoelectric effect device junction array subsystem without temporary filler material in substrate holes in accordance with an exemplary embodiment;

FIG. 5 is a top view of a representative thermoelectric effect device junction array subsystem with air gaps surrounding each junction in accordance with an exemplary embodiment;

FIG. 6 is a cross-sectional view of a thermoelectric effect device junction array subsystem having a first layer of thermoelectric effect device junctions and a second layer of thermoelectric effect device junctions with the second layer being stacked on top of the first layer in accordance with an exemplary embodiment;

FIG. 7 is a cross-sectional view of a thermoelectric effect device junction array system with a layer of focusing lenses on top in accordance with an exemplary embodiment;

FIG. 8 is a cross-sectional view of a thermoelectric effect device junction array system having a layer of focusing lenses on top and a heat transfer substrate on the bottom in accordance with an exemplary embodiment;

FIG. 9 is a cross-sectional view of a thermoelectric effect device junction array system having a layer of focusing lenses on top and an array cooling system coupled to thermoelectric effect device junctions substrate in accordance with an exemplary embodiment; and

FIG. 10 is a cross-sectional view of a thermoelectric effect device junction array system having a layer of focusing lenses on top and a phase change heat sink on the bottom in accordance with an exemplary embodiment; and

FIG. 11 is a cross-sectional view of a thermoelectric effect device junction array system having a layer of focusing lenses on top and a convective heat sink on the bottom in accordance with an exemplary embodiment;

### DETAILED DESCRIPTION

The present invention makes use of a fundamental device commonly known as a thermoelectric effect device or thermocouple. Thermoelectric effect devices generate electricity by virtue of having been formed as a metallic, bonded junction of two dissimilar metals. When the materials are differentially heated, e.g., a temperature differential is created between either ends of the two, single metal, conductors of the dissimilar materials and the physical junction of the two dissimilar metals, a voltage is produced across the circuit of two leads. This is known as the thermoelectric effect or Seebeck effect. Such thermoelectric effect devices can consist of the bi-metallic junction and interconnecting circuit elements, or “leads”, comprised of a single material. These interconnecting circuit elements are cooled with respect to the thermoelectric effect device junctions. In an exemplary embodiment, a system can consist of thermoelectric effect device junction arrays produced on a substrate of thermally conductive material such as plastic or ceramic. These constructions could be formed, for example, by way of thin film or chemical deposition or by three dimensional (3D) printing of metals. Each individual thermoelectric effect device junction can produce a direct current voltage directly proportional to the temperature differential that exists between the junctions of two dissimilar metals and the conductive leads coupled to these junctions. In an exemplary embodiment, a single junction comprising constantan and iron can generate a voltage of approximately 50 μV/° C. By coupling, e.g., serially, a plurality of similar junctions, the voltage that is generated can be cumulative and can generate direct current which can be used as a solar energy produced source of electrical power. The voltage produced by such an array is further multiplied by the temperature differential between the thermoelectric effect device junctions and the leads. This temperature differential can be as high as the phase change temperature of the metals comprising the junction. For example, the phase change temperature can be approximately 700° C. for Iron.

The efficiency can be further enhanced by creating small thermoelectric effect device junctions and focusing the solar radiation directly and only onto these small thermoelectric effect device junctions rather than on the entire area of the array. This can be accomplished using one or more lenses. For example, an array of focusing lenses substantially direct the solar radiation upon a spot containing the thermoelectric effect device junction or allowing the impinging solar radiation to fall substantially upon the thermoelectric effect device junctions using a simple collimating lens. The radiation not being focused directly upon the thermoelectric effect device junction can be reflected back into space by a reflective coating surrounding the thermoelectric effect device junction array area. A portion of the energy produced by the array can be used as electrical energy for a cooling system. For example, a cooling system can be coupled to an array with the cooling system pumping a non-solid, e.g., a fluid or a gas, to remove heat from the array. Heat removal can be enhanced by using a phase change material coupled to the substrate assembly which, in turn, is cooled by the pumping of a gas or liquid. In either case, the thermoelectric effect device interconnecting circuit elements, coupled to the bottom or lower substrate, can be cooled with respect to the thermoelectric effect device junctions. Cooling of the substrate can create or enhance the temperature differential necessary in order to generate electricity. The heat that is removed from such a cooling system can be stored or recovered to further enhance the overall system level energy efficiency.

In one or more exemplary embodiments, a system can be manufactured by creating one or more thermoelectric effect device junctions sequentially and vertically stacked upon the top of the first layer of thermoelectric effect device junctions. For example, a first layer can comprise of a first material, e.g., substantially constantan and a second layer can comprise a second material, e.g., substantially iron. A third layer of constantan with a separate, cooled interconnecting circuit element, can be deposited upon the first layer of iron of the thermoelectric effect device junctions. The system can include additional layers, alternating between the first and second materials. Thus, each layer can create multiple energy generators in the vertical dimension multiplying the overall junction array quantity thus increasing the system efficiency per unit of area of the array. In such embodiments, the circuit elements can be isolated by one or more layers of one or more dielectric materials. Each subsequent thermoelectric effect device junction assembly can be electrically coupled. For example, the thermoelectric effect device junction assemblies can be electrically coupled in series or in parallel thereby cumulating the power generated in a manner most compatible to the end device use of the electrical power.

In one or more exemplary embodiments, to increase the efficiency of energy generation, the thermoelectric effect device junctions and a portion of the interconnecting circuit elements can be constructed to form a mechanical bridge over an air gap to reduce the thermal conduction from the junctions to the underlying substrate.

In one or more embodiments, the thermoelectric effect device junction interconnecting circuit elements can be coupled to one another using a thermally resistant material. This method increases the resistance to thermal heat transfer from the hotter thermoelectric effect device junctions through the interconnecting circuit elements to the underlying substrate, creating a greater thermal temperature differential and reducing the heat load required for substrate cooling.

In one or more exemplary embodiments, a predetermined series of the thermoelectric effect device junctions can be coupled to one another and then the array coupled to a current collecting power bus, e.g., via diodes. This circuit arrangement can enable each thermoelectric effect device array to be limited to a predetermined voltage and therefore to limit the current generated by such an array. Limiting the cumulative current generation directly can limit the size of the interconnecting circuit elements required to transfer the current at a low or lower resistance. By summing the output of multiples of such arrays, the overall power generated is not limited and the electrical leads conducting the larger amounts of current can be physically larger as they do not need to be cooled with respect to the thermoelectric effect device junctions. The cumulation or summation of power from multiple array subassemblies can be optimized for either voltage or current as desired. Since each thermoelectric effect device junctions array can be controlled in this manner of current generation capability, the interconnecting circuit elements utilized in each thermoelectric effect device junction array can be limited in physical size. By limiting the interconnecting circuit element's size, the three dimensional volume of these connections can be maintained to a minimum value, which can further restrict the thermal transfer from each thermoelectric effect device junction to the interconnecting circuit elements.

In one or more exemplary embodiments, the cooling fluids used for cooling the solar energy conversion system can be pumped into a heat exchanger and used for hot water storage or direct heating augmentation.

Embodiments of the present invention relate to an exemplary system consisting of a multiple set of primary subsystems comprised of the following:

A primary substrate assembly of high temperature materials upon which the thermoelectric effect device junctions and ancillary circuitry can be deposited. This assembly provides the structural infrastructure for the subsequent elements described below. The exemplary embodiment can use ceramic plates bonded together. Other materials such as high temperature plastics which possess the high temperature characteristics enabling vapor deposition of multiple metallic layers or two or three dimensional (2 or 3D) metallic printing techniques as well as possessing a high thermal transfer rate can be used. These plates (substrates) facilitate the thermal transfer of heat from thermoelectric effect device interconnecting circuit elements to the substrate and subsequently to the coolant assembly. In the exemplary embodiment the upper substrate plate can have holes corresponding to the location of each thermoelectric effect device junction. These holes can be filled during manufacturing operations with a material possessing a melting temperature that is lower than either the material comprising the substrate or the materials comprising the thermoelectric effect device junction. This material can fill the substrate holes over which the dissimilar materials compromising the thermoelectric effect device junctions are deposited. The holes can be larger than the area comprised by the thermoelectric effect device junctions to ensure that an air gap surrounds or substantially surrounds the thermoelectric effect device junctions except for the interconnecting circuit elements which can carry the signal and power to the next thermoelectric effect device junction in the assembly. The air gap can be produced by melting the filler material after the thermoelectric effect device junctions and circuit elements are deposited. This primary plate can be bonded to a second, bottom substrate or lower substrate. The bonding of these two, or more, substrates can thermally isolate the thermoelectric effect device junctions while providing a direct thermal path which can collect the heat transferred by the interconnecting circuit elements which are coupling these thermoelectric effect device junctions in series. The bottom or lower plate can be used as the cooling mechanism or can be the element in contact with a cooling subassembly enabling the heat to be removed from the primary assembly.

The assembly comprising the power generating panel system can be assembled from a multiple number of subassemblies of multiple thermoelectric effect device junctions and associated interconnecting circuit elements arranged in series. These assemblies can enable the interconnecting circuit elements to be sized progressively larger as currents increase. Alternatively, the thermoelectric effect device arrays can contain a limited number of thermoelectric effect device junctions connected in series, e.g., a 1,000, with electronic circuit elements such as electronic diodes incorporated to effect a cumulative value of voltage or current as required. The use of such a circuit is optional as the thermoelectric effect device array can be assembled either in series or in parallel as required for optimal performance. When connected in series, the voltage can be added until a maximum desired voltage is attained. When connected in parallel the current can be added at the voltage level of the total connected array. As an example, low voltage, low current applications such as powering LEDs can utilize less thermoelectric effect device junctions.

The array system can further comprise one or more lenses or reflector subassemblies to focus the solar energy onto the area of the thermoelectric effect device junctions. The one or more lenses or reflector subassemblies can also simultaneously reflect the unfocussed energy (not collected by the lenses) off of the substrate assembly. The assembly can comprise a plate (substrate) which can be isolated from the functioning elements by an air gap to provide thermal isolation of the reflective layers and the functional thermoelectric effect device junction elements and circuitry.

The system can further comprise a coolant subsystem to remove heat from one or more of the thermoelectric effect device interconnecting circuit elements. This heat energy can be transferred to the substrate assembly by way of the circuit elements being coupled to the substrate and then removed by a coolant subsystem. In the exemplary design, the cooling subsystem can comprise a material that absorbs the heat and undergoes a phase change. Such materials are commonly known as fusible alloys or as fusible eutectic alloys. These materials can be cooled by a secondary system using fluids which are pumped and flow against the phase change assembly and the heat collected removed in a heat exchanger device. Alternatively, the coolant subsystem can comprise a heat sink to directly transfer heat from the thermoelectric effect device array to a fluid such as air or water. A system of subsystem can convert and/or store the energy collected by the array and the cooling can be incorporated to increase the overall system efficiency.

Energy enhancement gathering lenses can optionally be utilized to focus a greater incident area of solar radiation directly onto the thermoelectric effect device junctions and not onto the remainder of the assembly in general. The lenses can gather energy from an area larger than the thermoelectric effect device junctions and focus the energy only onto the actual area comprising the thermoelectric effect device junctions. This can produce a temperature rise at the thermoelectric effect device junctions that is higher than can be achieved by unamplified direct solar impingement. A reflective layer can be incorporated to reflect the unused incident thermal energy back into the atmosphere and not have it absorbed by the assembly. The temperature rise provided by the lens assembly can be a multiple of the temperature rise that can be produced without any energy enhancing lens. One or more of the lens types can be used. The one or more lenses can be Fresnel lenses, collimator lenses, or any lenses that can assist in focusing the solar radiation onto thermoelectric effect device junction.

A multiple number of these thermoelectric effect device arrays can be coupled to a larger array to form an assembly of multiple thermoelectric effect device arrays.

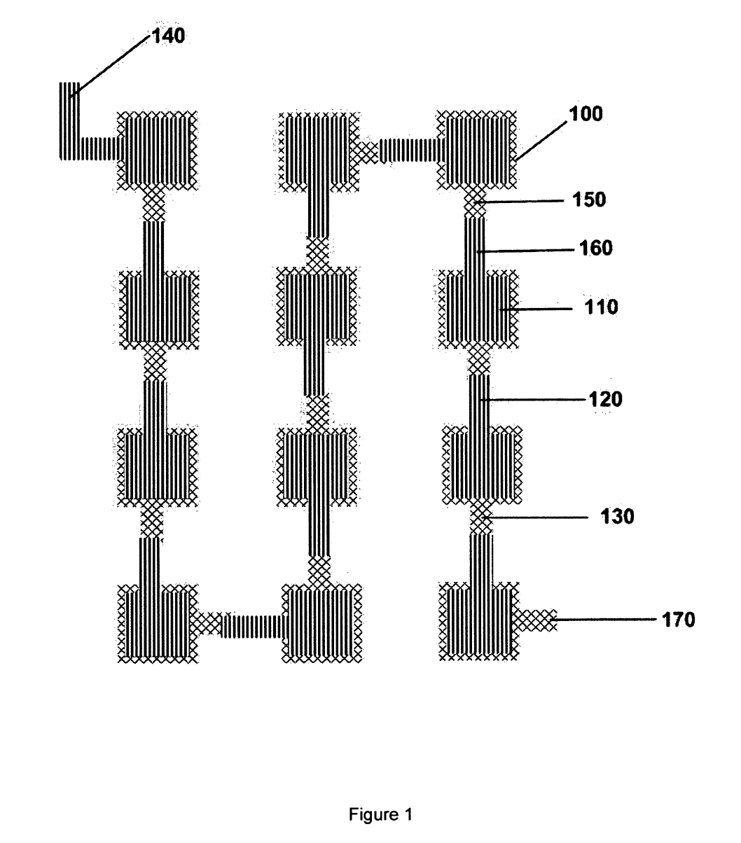

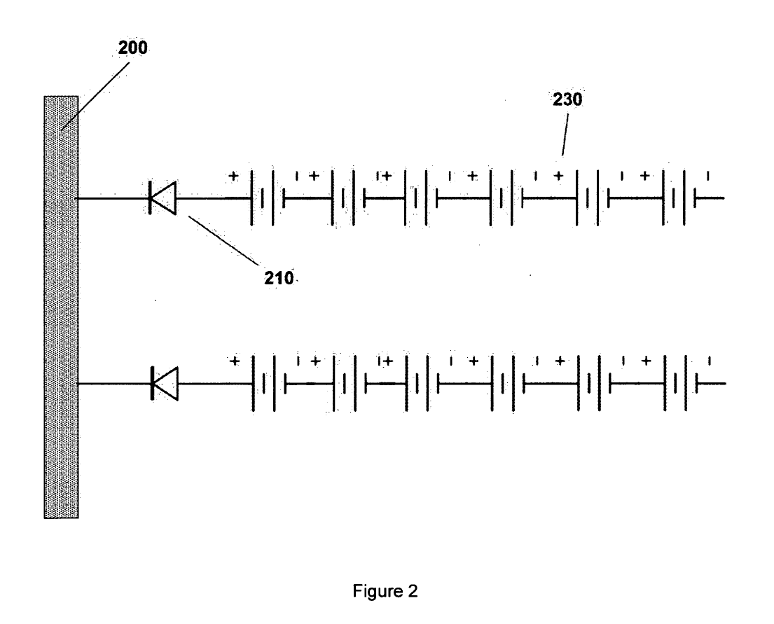

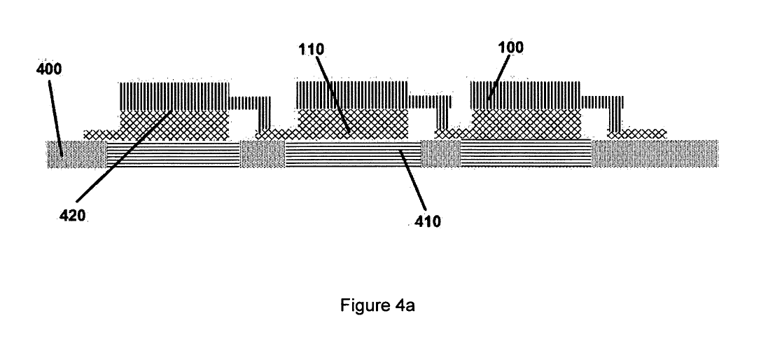

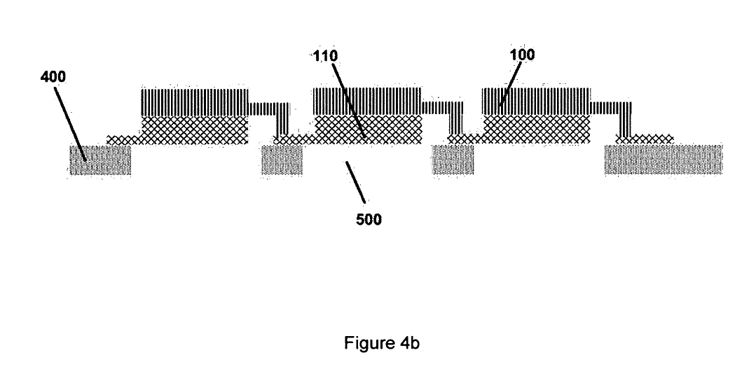

Referring to FIG. 1, a top view of a thermoelectric effect device array system with each of the junctions serially coupled in accordance with an exemplary embodiment is illustrated. This figure illustrates the opposite polarity serial connectivity of individual thermoelectric effect device junctions and the interconnectedness of individual thermoelectric effect device junctions to achieve a cumulative power array. As shown, the positive polarity is illustrated as 150 and the negative polarity as 160. The thermoelectric effect device junctions are created through the deposition (overlay) of one material upon another. In the exemplary embodiment these materials can be iron and constantan but any two dissimilar metal materials producing a voltage potential in the presence of temperature difference can be used. The thermoelectric effect device junction can be formed by first depositing a layer of material A 100 upon a dielectric substrate 400 (FIG. 4) followed by a second layer of material B 110 The interconnecting circuit elements 120, 130 can be made of the same material as the thermoelectric effect device junctions and can be deposited simultaneously with each material A or B as a seamless circuit element. The thermoelectric effect device junctions can be deposited on a dielectric substrate 400. In one or more exemplary embodiments this substrate material can be ceramic but high temperature plastics and other materials can also be used. These interconnecting circuit elements layers can be smaller in initial arrays and increased in size as the power generated increases with more interconnected thermoelectric effect device junctions. Alternatively, these element areas can also remain small and the power collected can be unidirectionally transported to a power bus 200 (FIG. 2). One or more devices can be utilized between the layers of the array to to prevent reverse current flow. The resulting current can be subsequently collected in a cumulating current (power) bus, 200, in order to maintain the smaller number of interconnected thermoelectric effect devices and, consequently, the physical size of each panel of arrays. Electrical power can be transferred from either a grounding connection or from other thermoelectric effect device junctions arrays through an input connection 170. Power can be transferred out of the array through a similar element, 140, to another thermoelectric effect device junctions array or to a power collecting bus or from the entire panel array to an electrical grid or power conversion subsystem 320.

In the exemplary assembly, the thermoelectric effect device junctions can be formed by a vapor deposition process in which the metal layers comprising the thermoelectric effect device junctions themselves as well as the associated respective interconnections and dielectric layers can be deposited successively with each layer utilizing a mask to shield those areas which are not to receive layering. Subsequent layering can be accomplished by using a different mask for each layer. The mask location can be precisely determined by the use of locating pins which protrude through the ceramic or thermally conductive plastic substrate into corresponding holes in the masks. The positive connective leads 150, from each thermoelectric effect device junction can be connected to the negative connective leads 160, traces in a serial fashion.

Referring to FIG. 2, an illustration of an optional embodiment of the exemplary system wherein the power generated from thermoelectric effect device junction arrays is transferred to a power bus through an electronic circuit is illustrated. In this embodiment, a unidirectional current collector 210, such as a diode, can collect current from one or more thermoelectric effect device junction arrays and prevent reverse current flow from a power bus, 200. The transference of power through a diode can prevent any reverse current and subsequent power loss. In the figure, the thermoelectric effect device junction arrays 230, are shown connected through a diode 210, onto a power bus 200, where the power is transported from the array to another element of the system.

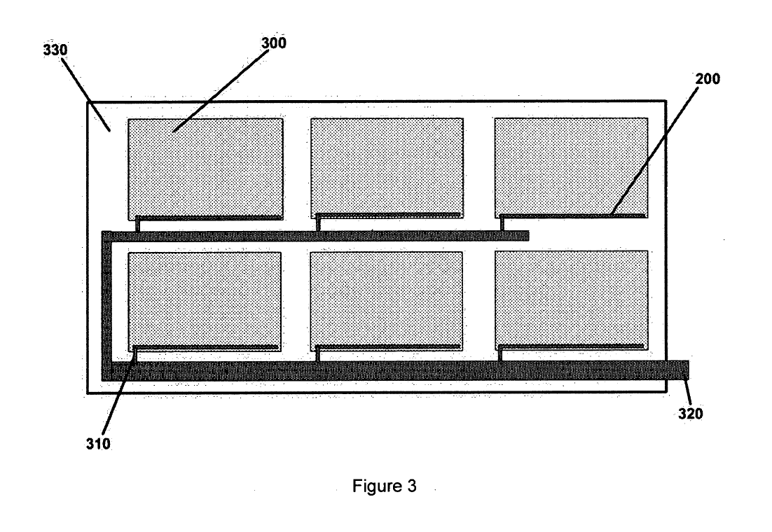

Referring to FIG. 3, a top view of an exemplary embodiment of several individual thermoelectric effect device diode array subassemblies, 300, are connected to a common power bus, 320, on a panel assembly. The individual arrays 300 can be attached to a panel substrate 330. Cooling can be accomplished either as individual array subassemblies 300, or as a panel assembly 330. The power bus 200 from each array sub panel can be connected to a larger capacity power bus 310, and power can be outputted from the panel assembly to the electrical grid, or other usage such as storage or connection to another panel assembly, at output connection on bus 320. This embodiment enables each sub array to utilize interconnecting circuit elements which can transport small currents which are cumulatively transported in larger capacity buses. This enables each array to be cooled efficiently since the buses 310 and 320 do not have to be cooled.

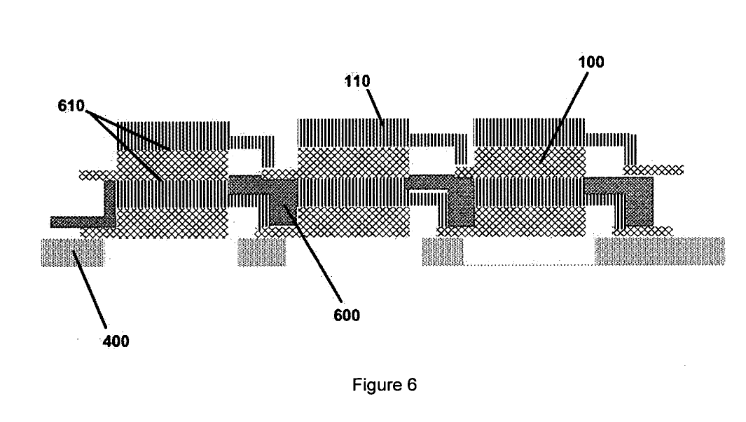

Referring to FIG. 4a, a cross sectional view of the thermoelectric effect device junction elements and the interconnecting circuit elements in an array formation as deposited on the primary substrate in accordance with an exemplary embodiment is illustrated. The primary substrate, 400, can be a material upon which metal layers are deposited via a deposition process. This substrate can include holes which are filled with a temporary filler material 410. In the exemplary embodiment, the filler material can be a low melting temperature metal such as zinc, tin, lead and their alloys or commercial fusible metals such as Field's Metal, an alloy of bismuth, tin and indium. The use of such a filler material enables the layers of thermoelectric effect device junctions, 110 and 100, to be deposited directly upon the upper surface of the temporary filler material 410 during manufacture. The thermoelectric effect device junction formed from the overlapping deposition of two dissimilar materials 420, is illustrated. It should be noted that this junction can be created with the upper layer of material B 110, being fused directly with and into the surface of material A 100. A layer of dielectric material to electrically isolate the thermoelectric effect device junction layers can be utilized and is shown as 600 in FIG. 6.

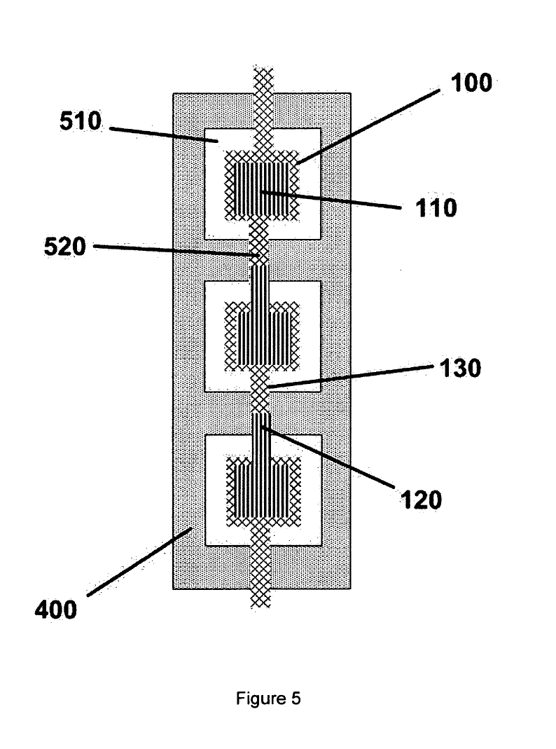

Referring to FIG. 4b, a cross sectional view of the exemplary embodiment illustrating the system of FIG. 4a with the filler material 410 removed from the thermoelectric effect device junctions. This temporary filler material can have a lower melting point compared to the melting point of the other materials in the thermoelectric effect device junctions. Thus to remove the temporary filler material, the substrate assembly can be heated to a temperature which causes the material 410 to melt and flow out of the bottom of the hole in the substrate 400. The resulting assembly positions the thermoelectric effect device junctions directly over a void 500 in the substrate 400. The thermoelectric effect device junctions and interconnecting circuit elements can be coupled to the substrate through the interconnect circuit elements 120, 130 which can be directly attached to the substrate 400. This assembly is shown from a top view in FIG. 5.

Referring to FIG. 5, a top view of the array assembly illustrating the air gap surrounding the thermoelectric effect device junctions and showing the interconnecting elements connected to the thermoelectric effect device junctions and affixed to the substrate in accordance with an exemplary embodiment is illustrated. In this figure, the array assembly after the temporary filler material has been removed is shown. The thermoelectric effect device junctions 420 comprises a first material A 100 and a second material B 110. The junction of the two dissimilar materials A and B are held suspended over the air gap 510 by the interconnecting circuit elements 120, 130. The interconnecting circuit elements 120, 130 can be coupled to the substrate 400, and serve to position the thermoelectric effect device junctions directly over the air gap 510. In this manner the thermoelectric effect device junctions can be thermally isolated as being connected to the substrate only through the interconnecting circuit elements thus enhancing the temperature differential across the two dissimilar metals. It should be noted that a layer of dielectric material may be used to electrically isolate the areas of circuit element overlap if a subsequent thermoelectric effect device junctions layer is deposited directly upon the first thermoelectric effect device junctions.

Referring to FIG. 6, a cross sectional view representation of the exemplary embodiment illustrating the vertical placement of additional thermoelectric effect device junctions 610 upon one another to further increase the power generation. Electrical isolation of interconnecting circuit elements is achieved by a layer of dielectric material 600.

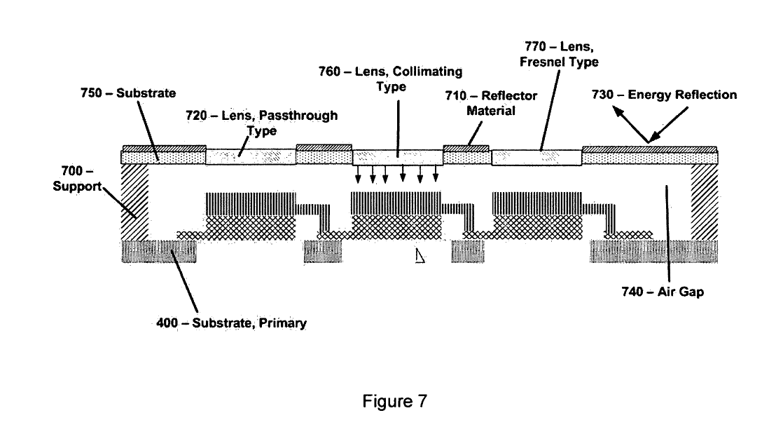

Referring to FIG. 7, a cross sectional view representation of the array assembly in accordance with an exemplary embodiment is illustrated. As shown, the array assembly can comprise a substrate 750, multiple lenses 720, 760 and 770, positioned directly over the thermoelectric effect device junctions. These lenses can be simple openings, 720, permitting solar radiation to pass through them unaltered or a type of collimating lenses 760 as shown, or they can be energy collecting devices 770 such as a Fresnel type, which gather additional area amounts of energy to be focused directly upon the thermoelectric effect device junctions, or any combination thereof. The portion of this substrate not containing lenses can be coated with a highly reflective material 710 which can serve to reflect the unused portion on the incident radiation, 730, back into the atmosphere and does not get absorbed as thermal energy. Supports 700 can be used to position the substrate, 750, above the array assembly substrate 400. The support 700 and substrate 750 can be sealed during assembly to prevent intrusion enabling the air gap 740 to be filled with a specific gas composition or evacuated to form a vacuum.

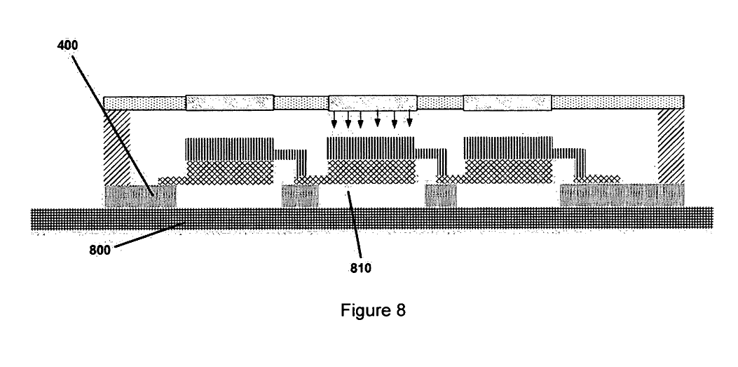

Referring to FIG. 8, a cross sectional view of the assembly of FIG. 7 is shown with an additional substrate 800 in accordance with an exemplary embodiment. This bottom substrate 800, can complete the thermoelectric effect device array assembly as a power generating sub system. This assembly of substrate 400 and 800, can be sealed creating the air gap 810 beneath the thermoelectric effect device junctions elements. A variant of this exemplary embodiment assembles the bottom substrate, 800, to the primary substrate 400 in a vacuum thereby eliminating the gas interface between the substrates 400 and 800, reducing the thermal transfer due to gaseous conduction. This further increases the thermal isolation of the thermoelectric effect device junctions as the air is not present to effect thermal transfer.

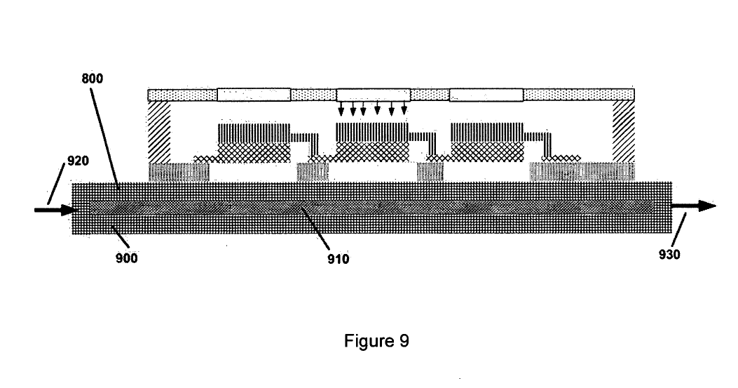

Referring to FIG. 9, a cross sectional view of an array coupled directly to a cooling assembly is illustrated. In this exemplary embodiment, substrate 800 can be coupled as a sealed assembly comprised of substrate 900 (with end caps) to the assembly of FIG. 8. In this cooling method a fluid can be pumped into the assembly thru inlet port 920 and can exit the assembly at outlet port 930.

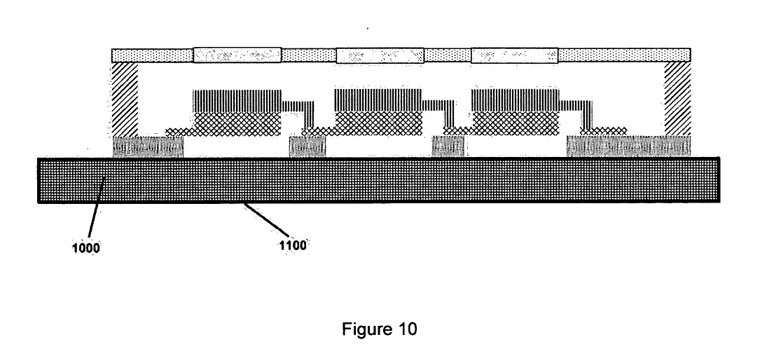

Referring to FIG. 10, an alternate cooling method for extracting the heat from the thermoelectric effect device array in accordance with an exemplary embodiment is illustrated. As shown, a cross sectional view of the array of FIG. 8 is shown assembled onto a larger area enclosure 1100. This enclosure can be larger than any individual array panel thus enabling several arrays to be attached to a single cooling subassembly. The cooling sub system is illustrated in the exemplary embodiment as a phase change material filled cavity, 1000. It should be noted that this enclosure 1100, may be equipped with inlet and outlet ports, 920 and 930, and fluids (liquid or gaseous) may be pumped to cool the phase change material 1000 as it heats. The material, 1000, would have channels manufactured in it to permit cooling fluid flow.

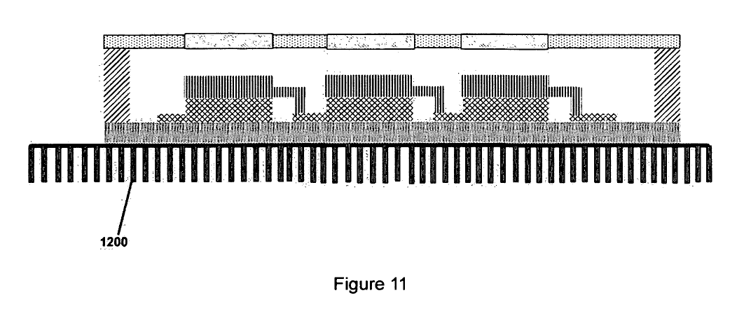

Referring to FIG. 11, an alternate cooling method for extracting the heat from the thermoelectric effect device array in accordance with an exemplary embodiment is illustrated. As shown, a cross sectional view of the array of FIG. 8 is shown assembled onto a substrate comprised of a thermally conductive device 1200 which transfers the heat directly to any fluid which is pumped through it. The cooling sub system is illustrated in the exemplary embodiment as a plastic molded shape conducive to transferring heat from the array to any fluid medium via conduction or convection.

### BEST MODE OF CARRYING OUT THE INVENTION

Thermoelectric effect devices are formed when two dissimilar metals are placed into intimate electrical contact with one another while maintaining interconnecting circuit elements at a temperature differential. When this occurs and a temperature differential exists between the interconnecting circuit elements and the bi-metallic junction, a voltage is generated. The voltage generates an electrical current. The combination of voltage and current results in the power generated. The thermoelectric effect device is not dependent on the size of the thermoelectric effect device junctions nor on the length of interconnecting circuit elements. In FIG. 1, it is illustrated that by using two or more metal layers, an array of thermoelectric effect device junctions with interconnected conductive leads and dielectric insulating layers, as required, can be formed through any of several processes including three dimensional (3D) metallic printing or vapor deposition. The system can also be formed through a combination of processes such as two dimensional (2D) or 3D metallic printing, 2D plastic or dielectric deposition and multiple combinations of all of the aforementioned processes. The thermoelectric effect device junctions and thermoelectric effect device junction arrays can be of any size commensurate with the manufacturing process. Nano size devices could be utilized. Ceramic or conductive plastic substrates are used as the exemplary embodiment due to cost, strength, heat tolerance, thermal conductivity and deposition compatibility. The interconnecting elements of the thermoelectric effect device junctions are the same as the layers of thermoelectric effect device junctions but are of one metal composition only. i.e., the interconnecting circuit elements are composed of one of the metals comprising the thermoelectric effect device junctions itself. The interconnecting circuit elements can be deposited to have a large area relative to the area of the thermoelectric effect device junctions as a means to effect greater cooling of the interconnecting circuit elements with respect to the thermoelectric effect device junctions.

The primary substrate upon which the thermo electric devices are deposited can be manufactured with a metallic layer such as copper (Copper/constantan junctions). In this exemplary system. The copper substrate can be chemically etched to produce the array of circuit elements required. When created in this manner, the thermo electric devices are formed with the deposition of only a single metallic layer, such as Constantan, reducing the complexity and enabling thermal energy transfer to the substrate through a highly efficient material and possessing greater flow area. 3D printing enables the deposition of the metallic layers as well as dielectric layering. 3D printing with laser sintering or electron beam sintering of the deposited metal material enables thermo electric device junction sizes that are correlated directly to the laser or electron beam precision.

Optimal performance results when the thermoelectric effect device junction of two dissimilar metals is heated to a maximum temperature below the phase change temperature limits of one of the two metals used to form the thermoelectric effect device junction. Maximum voltage is produced when the temperature differential between the thermoelectric effect device junction and the interconnecting circuit elements (leads) emanating from each of the two metals comprising the thermoelectric effect device are as high as possible. Consequently, cooling of the interconnecting circuit elements with respect to the junction itself enhances the maximum temperature differential. In the exemplary embodiment the thermoelectric effect device junctions are comprised of thin layers of dissimilar metals to minimize the thermal heating mass of the thermoelectric effect device junctions. The vapor deposition processes in general cause the metal layers to be deposited upon the horizontal surface available within the processing chamber. With reference to FIG. 4, as a means of optimally thermally isolating the thermoelectric effect device junctions, the substrate upon which the thermoelectric effect device junctions are deposited is manufactured with holes which are filled with a low temperature melting point substance. After deposition the material filling these holes is melted and falls from the hole leaving only the thermoelectric effect device junctions and interconnecting circuit elements over the hole area. The holes are larger in surface area than the surface area of the thermoelectric effect device junctions. In this manner the resulting thermoelectric effect device junctions are suspended over an air gap as shown in FIG. 5. The filler material can be a low melting temperature metal such as Zinc, Tin, Lead and their alloys or commercial eutectic fusible metals such as Field's Metal, an alloy of Bismuth, Tin and indium. With the holes filled, the deposition process layers materials upon a horizontal surface and the thermoelectric effect device junctions are formed as flat and continuous arrays.

With reference to FIG. 5, the filler material is removed by melting it and allowing it to flow from the substrate. Generally the filler material will be of a lower melting temperature than the thermoelectric effect device junction metal layers and thus can be heated from either the top or bottom surface or both simultaneously. The resulting thermoelectric effect device junctions are held in position by the interconnecting circuit elements shown in FIG. 6. The positive and negative polarity interconnecting circuit elements are deposited upon the substrate and each other in subsequent layering. The interconnecting circuit elements form a bridge over the air gap and serve to mechanically fasten the thermoelectric effect device junctions to the substrate. With reference to FIG. 6, a variant of the exemplary design includes a vertical layering of thermoelectric effect device junctions. By using a layer of dielectric material to prevent electrical short circuiting, successive thermoelectric effect device junctions can be formed without increasing the surface area of the array. This method also enables a single lens to focus heat on the thermoelectric effect device junctions and also enables thermal heating of the thermoelectric effect device junctions to occur vertically with cooling of the interconnecting circuit elements maintained as separate functioning for each layer of thermoelectric effect device junctions. Each vertical layer of thermoelectric effect devices increases the power output as each layer adds either one or more thermoelectric effect devices to the array, e.g., a layer of material A followed by a layer of material B followed by a third layer of material A constitutes a two thermoelectric effect device junctions.

With reference to FIG. 2, an exemplary electrical circuit is used to collect and distribute the power generated from the multiple thermoelectric effect device junction arrays and direct it to a power conditioning circuit off the array for subsequent use and distribution. The thermoelectric effect device junction arrays act like batteries connected in series. In this manner the voltage created by the array of thermoelectric effect device is summed. The current is passed thru a diode element to prevent reverse current flow into the array when the array is connected to additional arrays. A capacitor may also be connected in series and acts to both remove transient fluctuations as well as to store the power generated and enable subsequent transfer through a bus for use and distribution off of the array itself. In this configuration the multiplicity of circuits and the manner of interconnection enables the power bus to accumulate power in either a series or parallel manner. In the parallel implementation, the current is summed at a voltage chosen to be of a lower value, e.g. 5 VDC. This ensures that small interconnecting circuit elements can be utilized as the individual array current outputs can be handled by a low current capacity bus. In the alternative implementation, the arrays are interconnected in series thus generating a high voltage, e.g. 50 VDC, and can be used directly to power high voltage devices. The use of multiple parallel connected arrays enables the individual arrays to use small interconnecting circuit elements as none carry high values of electrical current.

With reference to FIG. 3, a large panel assembly of multiple power generating array sub assemblies can be used to collect the summation of power generated from each individual array. The use of a larger panel facilitates the cooling of the interconnecting circuit elements.

To increase the temperature differential between the thermoelectric effect device junctions and the interconnecting circuit elements, the interconnecting circuit elements are directly affixed to a substrate which is cooled to ensure that a temperature differential exists. The substrate can be cooled in multiple manners. In the exemplary embodiment, and with reference to FIG. 9, the primary substrate, 400, is affixed to a cooling subsystem creating a barrier between the cooling mechanism and the thermoelectric effect devices themselves. The liquid coolant sub system consists of a closed volume through which coolant is pumped. The coolant assembly is sealed and utilizes input and output tubes. Fluid is pumped into this chamber thought the use a liquid pump if the coolant is a liquid or through a fan if the coolant is gaseous. The effluent gas or liquid exiting the coolant assembly can be further cooled through the use a secondary heat exchanger or it can be transported to a heat storage device and stored for additional energy capture an subsequent usage. The method of cooling the thermoelectric effect device junctions arrays is not limited to liquid or gaseous mechanisms. With reference to FIG. 10, an alternative variant is shown in which a substrate of heat sink material is attached to the bottom substrate of the thermoelectric effect device junctions arrays. In such as assembly the thermal flow of heat from the interconnecting circuit elements are transferred directly to the heat sink substrate, This substrate is typically constructed of a material that undergoes a phase change from solid to liquid as it absorbs heat. This phase change material can be cooled in a secondary mode by pumping air or a liquid thru the assembly.

What is claimed is:

1. A device, system and method for a solar thermal conversion system that simultaneously converts solar thermal radiation into both electricity and heated fluid using thermoelectric effect devices to generate the electrical energy and a fluid (liquid or gas) to remove the heat from the thermoelectric device junctions and comprising:
a. A multilayered, serially connected array of thermoelectric effect devices forming a sub system of said devices having small junctions of two dissimilar metals and having either ends of these junctions intimately in contact with a cooled substrate;
b. A fluid cooling system where the energy removed from the thermoelectric device system is collected and used to as a secondary energy source to heat water or used directly to heat objects or other use.
c. A substrate of thermally conductive material upon which these thermo electric devices are assembled;
d. A fluid cooling system wherein the bottom substrate is cooled by causing a fluid to flow against it's bottom surface absorbing the heat of the thermoelectric device assemblies through the interconnecting circuit elements and which serves to maintain a temperature differential between the thermoelectric devices and their associated interconnecting circuit elements.
e. The energy to pump the cooling fluid flow is obtained directly from the electrical energy generated by the thermoelectric devices;
f. A further assembly of substrates constituting a lens, reflector, and coolant subassemblies.
g. A series of these subsystems interconnected so as to route their electrical output to be collected on uncooled circuit elements that do not require cooling and which enable large conductors to be utilized for greater current carrying capacity;

2. The system of claim 1 wherein the thermoelectric effect devices comprising an array are of near nanometer dimensions thus enabling the thermoelectric effect at a mechanical system size configuration that minimizes the thermal mass absorption required to create a temperature differential between the thermoelectric devices and their interconnecting circuit elements;
a. A manufacturing process that utilizes microelectronic processes of masking and vapor deposition or 2/3D metallic printing to produce near nanometer size element structures;
b. A solar thermoelectric effect system that utilizes dissimilar metal junctions layered at the atomic or nanometer dimensional level to reduce mass and thermal absorption in generating electricity.
c. A solar thermoelectric effect system that utilizes multiple layered thermoelectric effect junctions to concentrate thermal mass heat absorption.

3. The system of claim 1 wherein the thermoelectric device interconnected array is assembled using a combination of two dimensional (2D) or three dimensional (3D) metallic deposition processes and which may further use vapor deposition processes or 2D or 3D plastic printing processes to create additional layers of either conductors, dielectrics or reflectors;
a. A manufacturing process wherein the thermoelectric device junctions are assembled by depositing metallic particles and causing then to be sintered, melted or welded into a thin, metallic layer bonded directly to the substrate and to each other;
b. A process in which multiple layers of different metallic substrates can be deposited directly upon one another to form both thermoelectric devices as well as dielectric layers to isolate portions to the array electrically;
c. A process in which the thermo electric devices are and interconnected circuitry are placed in direct contact with the thermally conductive substrate;

4. The system of claim 1 wherein the thermoelectric effect device array power output is directed to a power collection bus via a diode preventing back flow of electrical current and allowing multiple arrays to output the power generated to the bus at low voltages enabling;
a. Cooling to be required only for the array subassemblies and not for the power bus;
b. Power to be collected at varying voltage levels to customize the power output for each application;
c. Low voltage power collection enabling small individual array sizes.
d. Electronic diodes to ensure current flow in a single direction without leakage from the power bus to the array.

5. The system of claim 1 wherein a combination of multiple cooling methods is used to achieve thermo electric device cooling through the substrate including;
a. The cooling methodology for the substrate is a material that undergoes a phase change with thermal absorption and;
b. The reclamation of the heated coolant to utilize said heat collected in a secondary energy recovery such as to heat cold water.

6. The solar thermoelectric effect system of claim 1, wherein the arrays are covered with a solar reflective material reflecting all of the impinging solar energy except for that coupled directly to the thermoelectric effect device junctions themselves and incorporating;
a. A system of lenses to focus energy from a larger solar incident impingement area onto the thermoelectric effect device junctions;

7. The solar thermoelectric effect system of claim 1 wherein the thermal radiation aperture system is sealed and evacuated of air to ensure that the thermal radiation is not dissipated via heating the trapped air and transferring said heat to the assembly via convection.

8. A manufacturing method and processes for the system of claim 1 wherein;
b. The solar thermoelectric effect system of claim 1 wherein the manufacturing processes for fabrication utilize vapor deposition or 2/3D printing processes to achieve nanometer (fractional mm) dimensions of elements;
c. The layering of dielectric materials onto the thermoelectric device elements to electrically isolate each thermoelectric effect device junction;
d. The layering of multiple thermoelectric effect device junctions in a vertical mode one on top of another;
e. The use of low cost thermally conductive plastics or ceramics as substrate materials;
f. The solar energy producing system of claim 1 wherein the thermoelectric effect device junctions are manufactured over an air gap to prevent direct thermal heating of the substrate;
g. The manufacturing process wherein the substrate holes over which the thermoelectric effect device junctions are deposited are filled with a low melting temperature substance which is heated and removed after the thermoelectric effect device junctions array assembly are manufactured;
h. The use of an air gap to ensure that the transfer of heat from the thermoelectric effect device junctions is restricted to the both ends of the two metal interconnecting leads.
